(19) United States
(12) Patent Application Publication
(10) Pub. No.: US 2017/0085220 A1
(43) Pub. Date: Mar. 23, 2017

(54) FLICKER NOISE, POWER CONSUMPTION, AND PULLING REDUCTION TECHNIQUES FOR VOLTAGE-CONTROLLED OSCILLATORS (VCOs)

(71) Applicant: QUALCOMM Incorporated, San Diego, CA (US)

(72) Inventor: Mazhareddin TAGHIVAND, Campbell, CA (US)

(21) Appl. No.: 14/856,847

(22) Filed: Sep. 17, 2015

(51) Int. Cl. H03B 5/12

(52) U.S. Cl. CPC H03B 5/1271; H03B 5/1228

(57) ABSTRACT

Certain aspects of the present disclosure provide methods and apparatus for reducing flicker noise, power consumption, and/or frequency pulling in voltage-controlled oscillators (VCOs). One example VCO generally includes an active negative transconductance circuit and a resonant circuit connected between a voltage rail for the VCO and the active negative transconductance circuit, wherein the resonant circuit is configured to resonate at a frequency of an oscillating signal generated by the VCO. The resonant circuit may provide high impedance between the voltage rail and the VCO at the frequency of the oscillating signal

### TECHNICAL FIELD

Certain aspects of the present disclosure generally relate to electronic circuits and, more particularly, to voltage-controlled oscillator (VCO) circuits incorporating techniques for reducing flicker noise, power consumption, and/or frequency pulling.

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology), 4G, 5G, or later system, which may provide network service via any one of various radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System-Time Division Duplexing), HSPA (High Speed Packet Access), GPRS (General Packet Radio Service), or EDGE (Enhanced Data rates for Global Evolution). Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3rd Generation Partnership Project (3GPP) Long Term Evolution (LTE) networks, and Long Term Evolution Advanced (LTE-A) networks. Other examples of wireless communication networks may include WiFi (in accordance with IEEE 802.11), WiMAX (in accordance with IEEE 802.16), and Bluetooth® networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

In order to transmit or receive data and/or control information, the radio frequency front end of the base station and/or the mobile station may include one or more frequency synthesizers to generate oscillating signals used for upconverting baseband signals and downconverting radio frequency (RF) signals. At least one of the frequency synthesizers may include a voltage-controlled oscillator (VCO) for tuning an oscillating signal to different frequencies. In modern communication systems, it is typically desirable to use VCOs with low phase noise and low power consumption. VCO pulling (also referred to as “frequency pulling”) is another problem for consideration when designing radio frequency front ends. In VCO pulling, an amplified RF signal output from a transmit path may have a frequency close to the VCO output frequency, may couple with an inductor in the resonant tank of the VCO, and may “pull” the VCO output frequency away from the desired frequency.

### SUMMARY

Certain aspects of the present disclosure generally relate to techniques and apparatus for reducing flicker noise, power consumption, and/or frequency pulling in voltage-controlled oscillators (VCOs) and digitally controlled oscillators (DCOs), which refer to the combination of a VCO driven by a control signal from a digital-to-analog converter (DAC). For ease of description, the remainder of the disclosure refers only to VCOs, but a person having ordinary skill in the art will understand that aspects of the disclosure apply to both VCOs and DCOs.

Certain aspects of the present disclosure provide a VCO. The VCO generally includes a first resonant circuit configured to control a frequency of an oscillating signal generated by the VCO; an active negative transconductance circuit connected with the first resonant circuit; and a second resonant circuit connected between a voltage rail for the VCO and the active negative transconductance circuit, wherein the second resonant circuit is configured to resonate at the frequency of the oscillating signal and to provide high impedance between the voltage rail and the first resonant circuit at the frequency of the oscillating signal.

According to certain aspects, the active negative transconductance circuit includes cross-coupled transistors, and the second resonant circuit is connected with one or more sources of the cross-coupled transistors. For certain aspects, the VCO further includes a third resonant circuit configured to resonate at the frequency of the oscillating signal and to provide high impedance between the voltage rail and a source of a first one of the cross-coupled transistors at the frequency of the oscillating signal, wherein the second resonant circuit is configured to provide the high impedance between the voltage rail and a source of a second one of the cross-coupled transistors, different from the first one of the cross-coupled transistors. For certain aspects, the cross-coupled transistors include n-channel metal-oxide semiconductor (NMOS) transistors, and the voltage rail may be an electrical ground. For other aspects, the cross-coupled transistors comprise p-channel metal-oxide semiconductor (PMOS) transistors, and the voltage rail may be a power supply voltage configured to supply power to the VCO. For certain aspects, the VCO further includes resistive elements connected in series between the sources of the cross-coupled transistors. In this case, the VCO may further include a capacitive element coupled between the first resonant circuit and the resistive elements. The capacitive element may be coupled between a center tap of an inductive element in the first resonant circuit and a node between the resistive elements. The resistive elements may include at least one of a resistor or a transistor biased in a triode region.

According to certain aspects, a resonant frequency of the second resonant circuit is adjustable and is configured to follow an adjustment by the first resonant circuit to the frequency of the oscillating signal.

According to certain aspects, the second resonant circuit is configured to provide the high impedance in a frequency band that includes the frequency of the oscillating signal over at least a portion of a tuning range for the VCO.

According to certain aspects, the second resonant circuit includes a self-resonating inductor configured to resonate at the frequency of the oscillating signal.

Certain aspects of the present disclosure provide a VCO. The VCO generally includes a resonant circuit configured to control a frequency of an oscillating signal generated by the VCO, an active negative transconductance circuit connected with the resonant circuit and comprising cross-coupled transistors, two or more resistive elements connected in series between sources of the cross-coupled transistors, and a capacitive element connected between the resonant circuit and the resistive elements.

According to certain aspects, the capacitive element is coupled between a center tap of an inductive element in the resonant circuit and a node between the resistive elements.

According to certain aspects, the resistive elements include at least one of a resistor or a transistor biased in a triode region.

According to certain aspects, the VCO further includes a bias current circuit for sourcing or sinking a bias current through the resonant circuit and the active negative transconductance circuit to generate the oscillating signal.

Certain aspects of the present disclosure provide VCO circuitry. The VCO circuitry generally includes a VCO comprising a first resonant circuit configured to control a frequency of an oscillating signal generated by the VCO and an active negative transconductance circuit connected with the first resonant circuit and comprising cross-coupled transistors; and a second resonant circuit configured to resonate at the frequency of the oscillating signal and connected between the VCO and a voltage rail (e.g., electrical ground or a power supply voltage).

According to certain aspects, the VCO circuitry further includes two or more resistive elements connected in series between sources of the cross-coupled transistors and a capacitive element connected between the first resonant circuit and the resistive elements. For certain aspect, the capacitive element is coupled between a center tap of an inductive element in the first resonant circuit and a node between the resistive elements. The resistive elements may include at least one of a resistor or a transistor biased in a triode region.

According to certain aspects, the VCO circuitry further includes a bias current circuit for sourcing or sinking a bias current through the first resonant circuit and the active negative transconductance circuit to generate the oscillating signal.

According to certain aspects, the second resonant circuit is configured to isolate the VCO from at least signals having frequencies of the oscillating signal and emanating from the voltage rail. The second resonant circuit may be configured to isolate the VCO by providing high impedance between the VCO and the voltage rail for the at least the signals having the frequencies of the oscillating signal.

Certain aspects of the present disclosure provide a method for reducing noise in an oscillating signal. The method generally includes generating the oscillating signal with a first resonant circuit of a VCO and isolating at least a portion of current, having frequencies of the oscillating signal and flowing in a voltage rail coupled to the VCO, via a second resonant circuit resonating at a frequency of the oscillating signal.

Certain aspects of the present disclosure provide an apparatus for reducing noise in an oscillating signal. The apparatus generally includes means for generating the oscillating signal comprising a first resonant circuit and means for isolating at least a portion of current, having frequencies of the oscillating signal and flowing in a voltage rail coupled to the means for generating, by resonating a second resonant circuit at a frequency of the oscillating signal.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIG. 4 is a block diagram illustrating voltage-controlled oscillator (VCO) pulling in an example transceiver front end.

FIG. 5A is a schematic diagram of an example physical circuit model for illustrating VCO pulling and a corresponding frequency spectrum.

FIG. 5B is a schematic diagram of an example physical circuit model with the addition of a resonant circuit between a VCO and the integrated circuit (IC) ground and a corresponding frequency spectrum, in accordance with certain aspects of the present disclosure.

FIG. 6 is a schematic diagram of an example VCO having an additional resonant circuit in an effort to reduce VCO pulling, in accordance with certain aspects of the present disclosure.

FIG. 7 is a schematic diagram adding a capacitor and two resistive elements to the example VCO of FIG. 6 in an effort to reduce flicker noise, in accordance with certain aspects of the present disclosure.

FIG. 8 is an example graph of phase noise versus frequency, comparing the flicker noise for the example VCOs of FIGS. 6 and 7 without and with the capacitor and two resistive elements, respectively, in accordance with certain aspects of the present disclosure.

FIG. 9 is a comparison of example waveforms for the VCOs of FIGS. 7 and 6 with and without the capacitor and two resistive elements, respectively, in accordance with certain aspects of the present disclosure.

FIG. 10 is a schematic diagram of an example VCO having a bias current source and the capacitor and two resistive elements of the example VCO of FIG. 7, in accordance with certain aspects of the present disclosure.

FIG. 11 is a schematic diagram of an example VCO having two additional resonant circuits in an effort to reduce VCO pulling, in accordance with certain aspects of the present disclosure.

FIG. 12 is an example graph of phase noise versus frequency, comparing the flicker noise for the example VCO of FIG. 11 both with and without the capacitor and two resistive elements, in accordance with certain aspects of the present disclosure.

FIG. 13 is a comparison of example waveforms for the example VCO of FIG. 11 both with and without the capacitor and two resistive elements, in accordance with certain aspects of the present disclosure.

FIG. 14 is a flow diagram of example operations for reducing noise in an oscillating signal, in accordance with certain aspects of the present disclosure.

### DETAILED DESCRIPTION

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and so on. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11, IEEE 802.16, Long Term Evolution (LTE) (e.g., in TDD and/or FDD modes), or some other standards. A TDMA system may implement Global System for Mobile Communications (GSM) or some other standards. These various standards are known in the art.

### An Example Wireless System

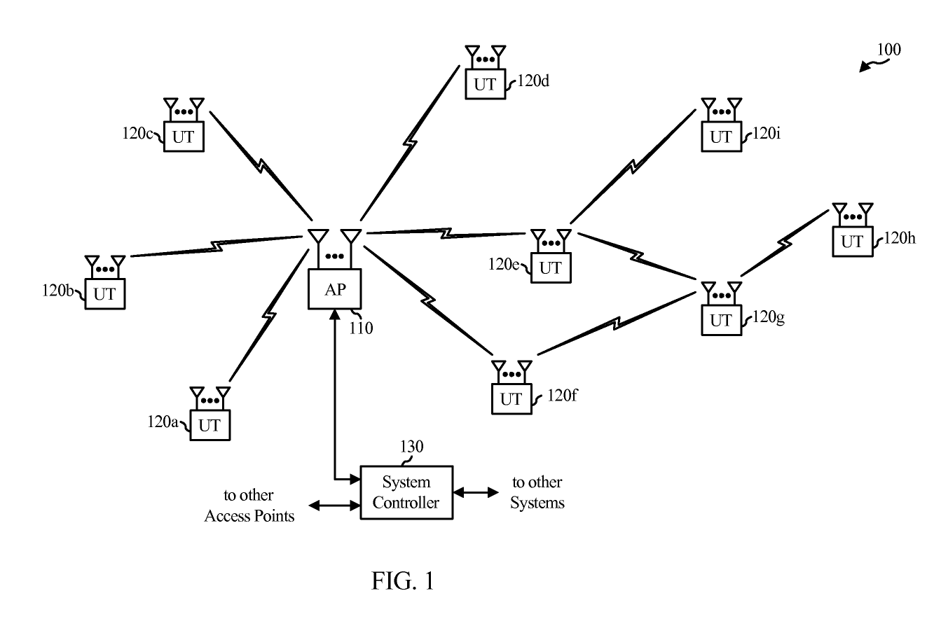

FIG. 1 illustrates a wireless communications system 100 with access points 110 and user terminals 120. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≧1). The Nᵤ selected user terminals can have the same or different number of antennas.

Wireless system 100 may be a time division duplex (TDD) system or a frequency division duplex (FDD) system. For a TDD system, the downlink and uplink share the same frequency band. For an FDD system, the downlink and uplink use different frequency bands. System 100 may also utilize a single carrier or multiple carriers for transmission. Each user terminal 120 may be equipped with a single antenna (e.g., in order to keep costs down) or multiple antennas (e.g., where the additional cost can be supported).

The access point 110 and/or user terminal 120 may include one or more frequency synthesizers to generate periodic signals used for signal transmission and/or reception. At least one of the frequency synthesizers may include a VCO implementing the techniques for reducing flicker noise and/or VCO pulling, in accordance with certain aspects of the present disclosure.

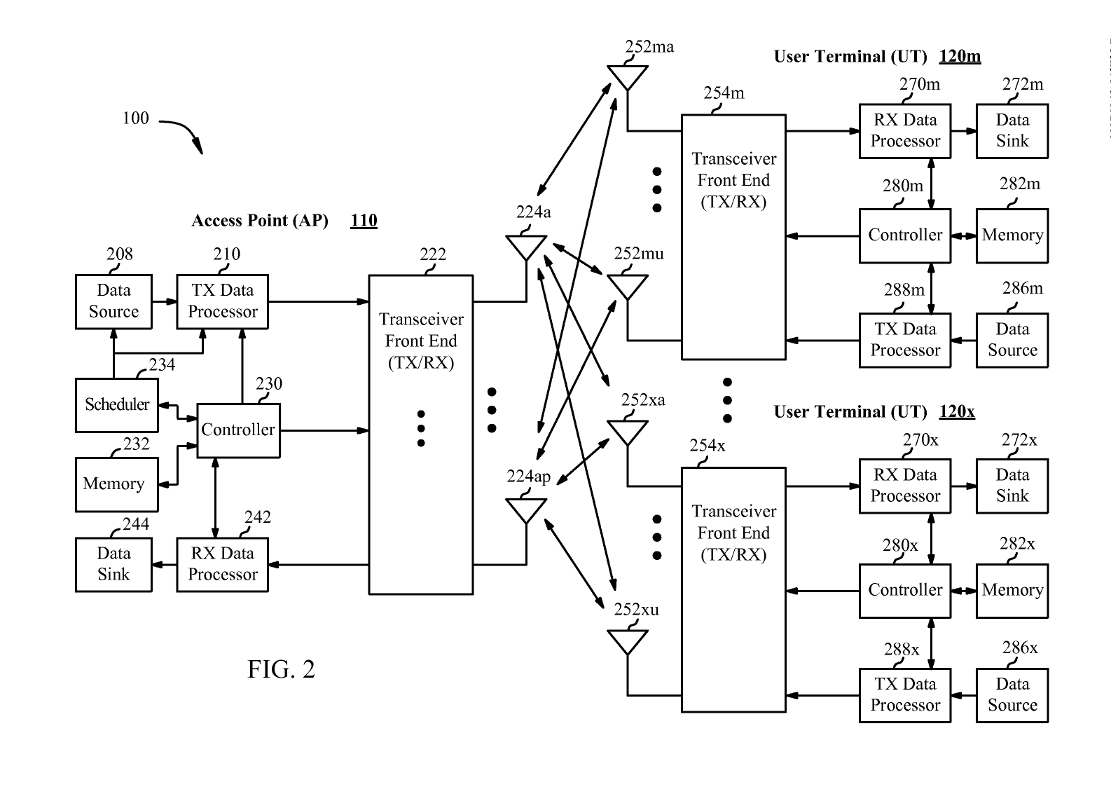

FIG. 2 shows a block diagram of access point 110 and two user terminals 120m and 120x in wireless system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

The transceiver front end (TX/RX) 222 of access point 110 and/or transceiver front end 254 of user terminal 120 may include one or more frequency synthesizers to generate oscillating signals used for signal transmission and/or reception. At least one of the frequency synthesizers may include a VCO implementing the techniques for reducing flicker noise and/or VCO pulling, in accordance with certain aspects of the present disclosure.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal TX data processor 210 may provide a downlink data symbol stream for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, TD-SCDMA, and combinations thereof.

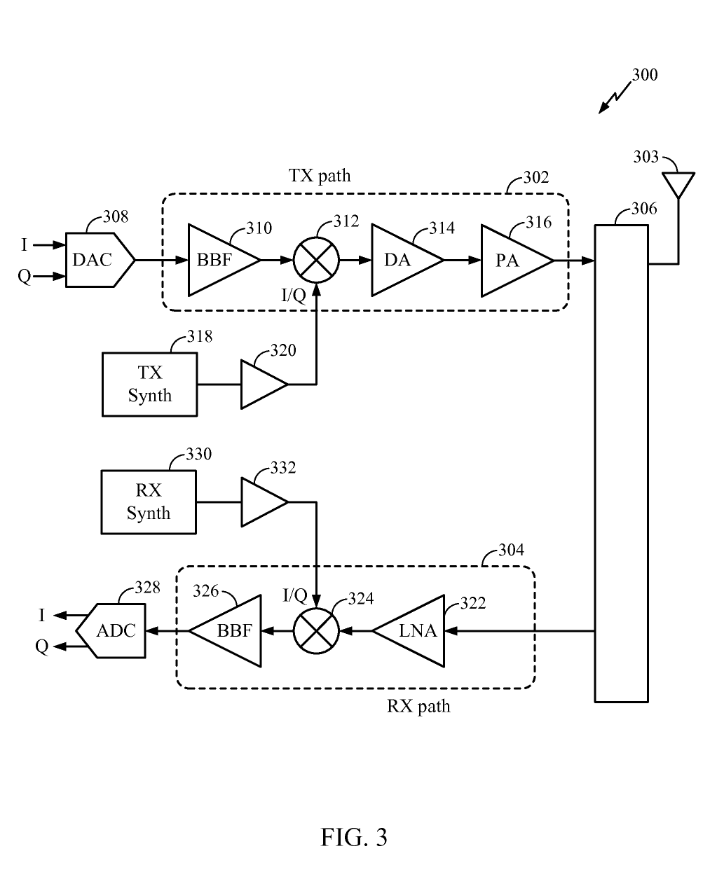

FIG. 3 is a block diagram of an example transceiver front end 300, such as transceiver front ends 222, 254 in FIG. 2, in accordance with certain aspects of the present disclosure. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which are amplified by the DA 314 and by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning to different frequencies indicates using a variable-frequency oscillator, which involves compromises between stability and tunability. Contemporary systems may employ frequency synthesizers with a VCO to generate a stable, tunable LO with a particular tuning range. Thus, the transmit LO may be produced by a TX frequency synthesizer 318, which may be buffered or amplified by amplifier 320 before being mixed with the baseband signals in the mixer 312. Similarly, the receive LO may be produced by an RX frequency synthesizer 330, which may be buffered or amplified by amplifier 332 before being mixed with the RF signals in the mixer 324.

The TX frequency synthesizer 318 and/or RX frequency synthesizer 330 may comprise a VCO implementing the techniques for reducing flicker noise and/or VCO pulling, in accordance with certain aspects of the present disclosure.

### Example Voltage-Controlled Oscillators

Modern communication systems may rely on low phase noise to obtain high signal-to-noise ratio (SNR) in both receive and transmit paths (e.g., RX and TX paths 304, 302). Phase noise is the frequency domain representation of random fluctuations in the phase of a waveform, such as the oscillating signal produced by a VCO. Whereas an ideal oscillator would generate a pure sine wave, real oscillators have phase-modulated noise components that spread the power of the oscillating signal to adjacent frequencies, resulting in noise sidebands. Oscillator phase noise may include low frequency flicker noise and white noise. Flicker noise is a type of electronic noise having a l/f power density spectrum, and although flicker noise appears as a low-frequency phenomenon, this low-frequency noise can be upconverted to frequencies close to the carrier frequency, which results in oscillator phase noise. As complementary metal-oxide-semiconductor (CMOS) processes scale, the flicker noise increases, which may prevent designing for the minimum channel length in the VCO.

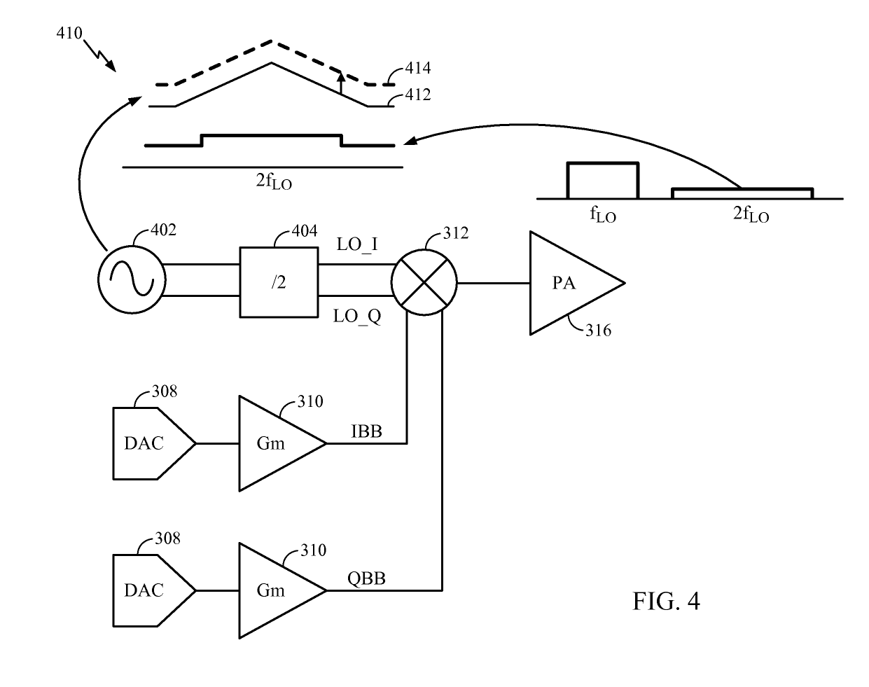

VCO pulling is another problem in designing radio frequency (RF) front ends. FIG. 4 is a block diagram illustrating VCO pulling in an example RF front end, in accordance with certain aspects of the present disclosure. The RF front end of FIG. 4 is similar to the TX path 302 of FIG. 3 and includes DACs 308 and amplifiers (e.g., transconductance (Gm) amplifiers) implemented as BBFs 310 for both in-phase (I) and quadrature (Q) signals, a mixer 312 for upconverting the I and Q baseband signals (IBB and QBB), and a PA 316. The I and Q baseband signals may be mixed with the local oscillator I and Q signals (LO_I and LO_Q) produced by a VCO 402 and a divide-by-2 (Div2) frequency divider 404, for example. In this case, if the periodic LO signals have a frequency designated as f_{LO}, the oscillating signal generated by the VCO 402 has a frequency of 2f_{LO}. In the case of a homodyne transmitter, the nominal frequency output by the mixer 312 and the PA 316 is near f_{LO} as illustrated. The second harmonic of the PA 316 at approximately 2f_{LO} falls directly within the VCO band. The corresponding VCO spectrum 410 illustrates the increase in the phase noise of the VCO 402 from a nominal phase noise level 412 to a higher phase noise level 414. This VCO pulling causes integrated phase noise (IPN) degradation, which degrades the error vector magnitude (EVM). One solution to avoid such VCO pulling would be to avoid operating the VCO at 2f_{LO}. However, operating the VCO at this frequency may be desirable because this may save area and power and avoid creating spurs in forbidden bands.

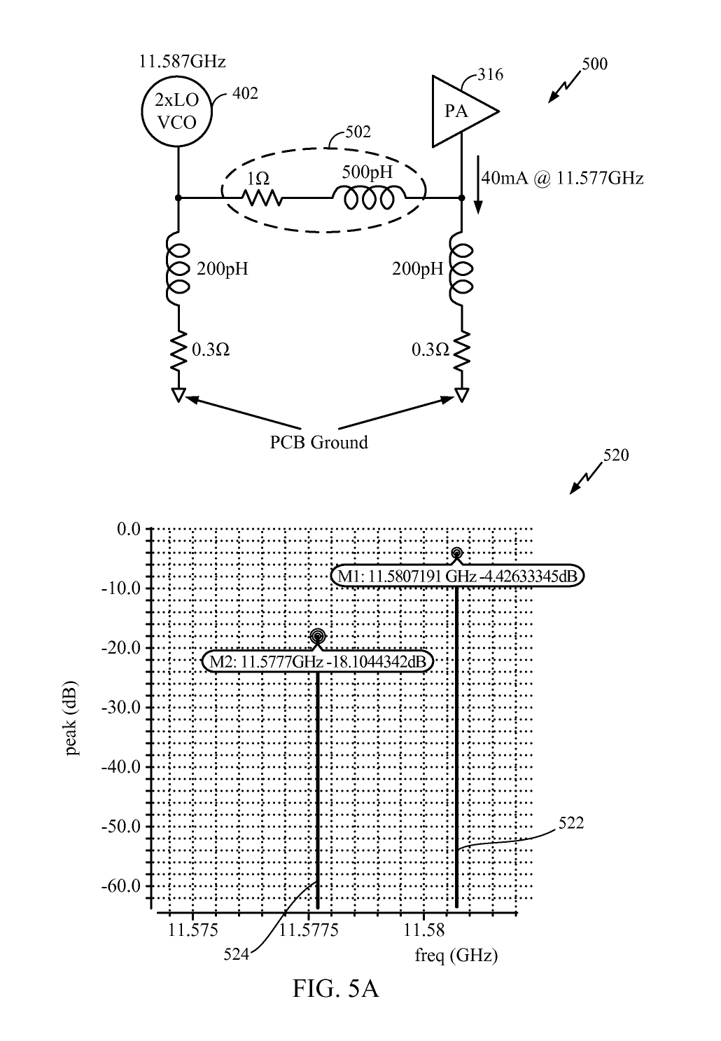

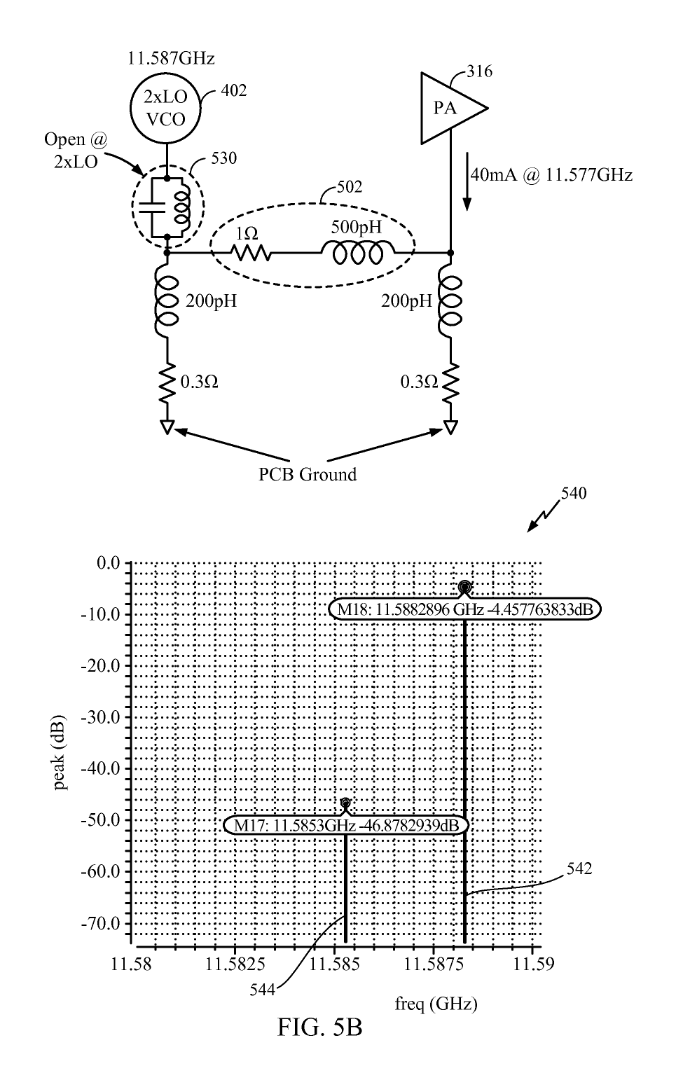

FIG. 5A is a schematic diagram of an example physical circuit model 500 for illustrating the VCO pulling mechanism of FIG. 4. Within a radio frequency integrated circuit (RFIC), there may be a ground routing 502 between the PA 316 and the VCO 402. Modeled as a 500 pH inductor in series with a 1Ω resistor, the ground routing 502 may provide a potential path for current having a frequency of approximately 2f_{LO} (e.g., 11.577 GHz as illustrated) to travel from the PA 316 to the VCO 402 operating at 2f_{LO} (e.g., 11.587 GHz as illustrated) and increase the phase noise. The remainder of the model 500 illustrates lumped parameters for the wafer level packaging (WLP) balls to a ground of a printed circuit board (PCB) to which the RFIC is soldered. The corresponding frequency spectrum 520 illustrates that there may be, for example, only 14 dB of isolation between the main tone 522 at 11.587 GHz from the VCO 402 and the second harmonic 524 from the PA 316.

Accordingly, what is needed are techniques and apparatus for reducing the flicker noise and/or frequency pulling in VCOs.

Certain aspects of the present disclosure introduce one or more additional resonant circuits designed to resonate at the VCO frequency and provide a high impedance path at this frequency to attenuate the PA's second harmonic and reduce VCO pulling. Certain aspects of the present disclosure add a capacitor and two resistive elements between the tuning voltage for the VCO and sources of cross-coupled transistors in the active negative transconductance circuit to reduce the flicker noise. These aspects may be combined in an effort to reduce both VCO pulling and flicker noise.

FIG. 5B is a schematic diagram of the example physical circuit model 500 of FIG. 5A with the addition of one or more resonant circuits 530 between the VCO 402 and an RFIC ground, in accordance with certain aspects of the present disclosure. The resonant circuit 530 is designed to resonate at the VCO frequency of 2f_{LO} (e.g., 11.587 GHz as illustrated). At its resonating frequency, the resonant circuit 530 presents a high impedance (Hi-Z) path to PA current having a frequency of approximately 2f_{LO} (e.g., 11.577 GHz as illustrated). Therefore, PA current traveling along the ground routing 502 of the RFIC at this frequency may be prevented from reaching the VCO 402 and influencing the frequency of the generated oscillating signal, thereby reducing VCO pulling. The corresponding frequency spectrum 540 illustrates that there may be, for example, 42 dB of isolation between the main tone 542 at 11.587 GHz from the VCO 402 and the second harmonic 544 from the PA 316. This example demonstrates an improvement of approximately 28 dB more isolation from the frequency spectrum 520 of FIG. 5A.

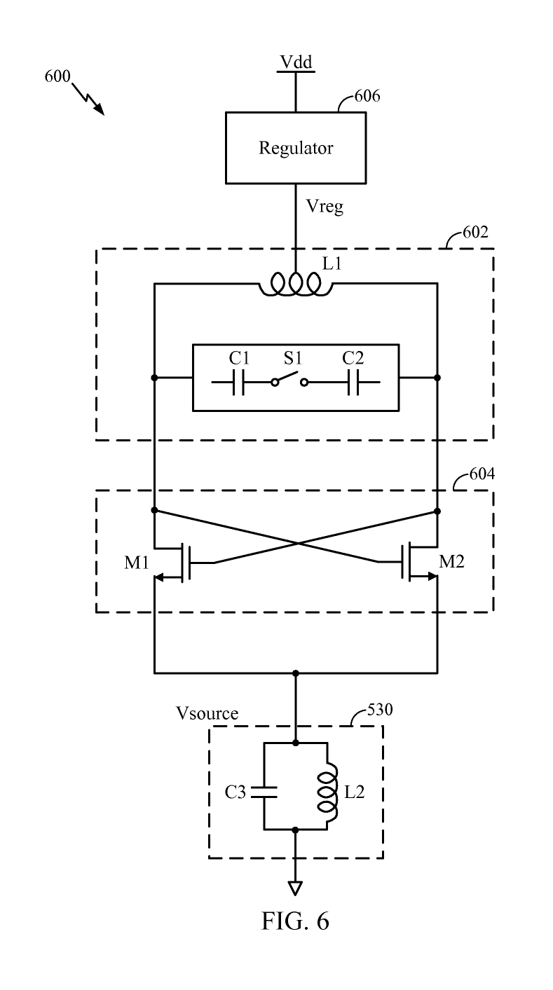

FIG. 6 is a schematic diagram of an example VCO 600, in accordance with certain aspects of the present disclosure. As illustrated, the VCO 600 has a resonant circuit 602 (also referred to as an inductor-capacitor (LC) circuit, a tank circuit, or a tuned circuit) and an active negative transconductance (−gₘ) circuit 604 connected with the resonant circuit 602. Certain aspects may include a bias current circuit (not shown here) for sourcing (or sinking) a bias current through the resonant circuit 602 and the active negative transconductance circuit 604 to generate an oscillating signal. As illustrated in FIG. 6, a pair of NMOS transistors M1 and M2 are cross-coupled to form the active negative transconductance circuit 604 that serves to cancel out the loss (due to parasitics) of the resonant circuit 602 and, thus, to sustain the oscillation mechanism. The resonant circuit 602 may include a center-tapped inductor L1 (or two series inductors) and a capacitor network (e.g., comprising capacitors C1 and C2) designed to oscillate at a certain resonant frequency. The inductor L1 and/or one or more capacitors in the capacitor network may be variable to adjust the VCO frequency within a tuning range. For certain aspects, the resonant circuit 602 may include one or more switches (e.g., represented by switch S1 in FIG. 6) used to select different combinations of capacitors in the capacitor network, thereby adjusting the resonance of the circuit. A regulator 606 or another circuit may provide an output voltage (Vreg) for tuning the inductor L1 (or the capacitors) and controlling the VCO frequency. The VCO 600 may receive power from a power supply voltage (e.g., Vdd) referenced to another voltage (e.g., electrical ground).

As described above, the VCO 600 may include an additional resonant circuit 530 between the active negative transconductance circuit 604 and electrical ground (or another reference potential for the VCO). The resonant circuit 530 may include an inductor L2 in parallel with a capacitor C3 and is designed to resonate at the same frequency as the resonant circuit 602. For certain aspects, the resonant circuit 530 may be designed with a relatively low Q to have a wide resonance bandwidth, which may be sufficiently wide to cover the tuning range of the resonant circuit 602. In this manner, the resonant circuit 530 can present high impedance to PA currents at any frequency within the VCO tuning range. For other aspects, the resonant circuit 530 may be programmable, where either or both inductor L2 and capacitor C3 are variable and can be tuned to match the VCO frequency as the resonant circuit 602 is tuned. In this manner, the resonant circuit 530 can track the resonant circuit 602 and present high impedance to PA currents at or near the VCO frequency. In this latter case, the resonant circuit 530 may have a relatively high Q to have a narrow resonance bandwidth.

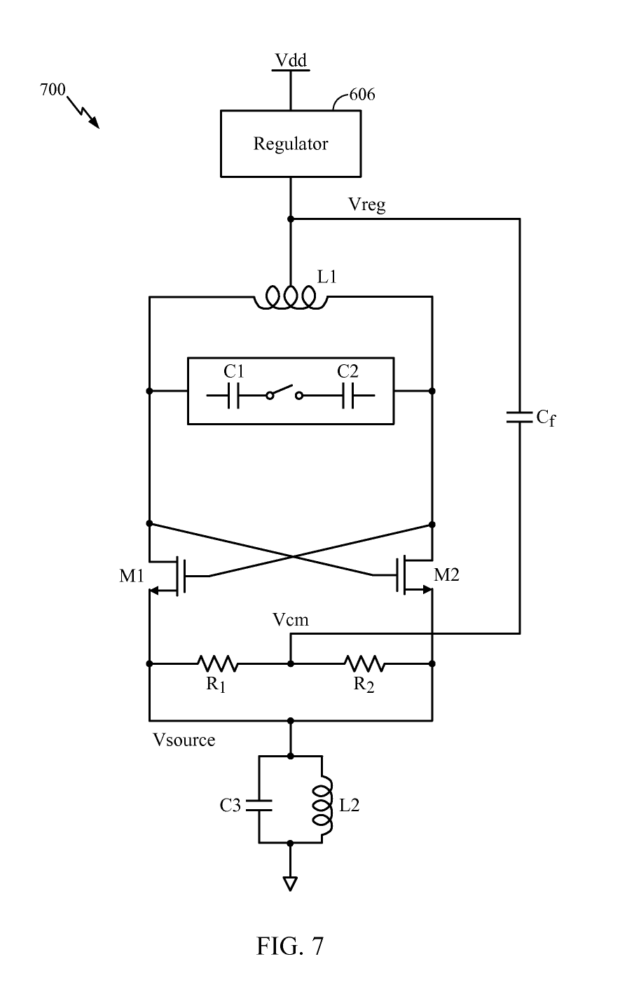

In the VCO 700 of FIG. 7, a capacitor Cf and two resistive elements have been added to the example VCO 600 of FIG. 6 in an effort to reduce flicker noise, in accordance with certain aspects of the present disclosure. The capacitor Cf may be connected between the center tap of the inductor L1 (or the output of the regulator 606) and a node between the two resistive elements, which is a common-mode voltage (Vcm) for the VCO 700. The other ends of the resistive elements may be connected separately with the active negative transconductance circuit 604 (e.g., at the sources of the NMOS transistors M1 and M2) and connected together with the additional resonant circuit 530 as shown in FIG. 7. The voltage at this common connection point may be labeled as “Vsource” as shown. The resistive elements may be implemented with polyresistors (e.g., resistors R1 and R2 as illustrated) or metal-oxide semiconductor (MOS) resistors, for example. The resistive elements may have a resistance value of approximately 20Ω, for example. For certain aspects, the resistive elements may be variable. The capacitor Cf may have a capacitance value of approximately 10 pF or 100 pF, for example. For certain aspects, the capacitor Cf may be tunable.

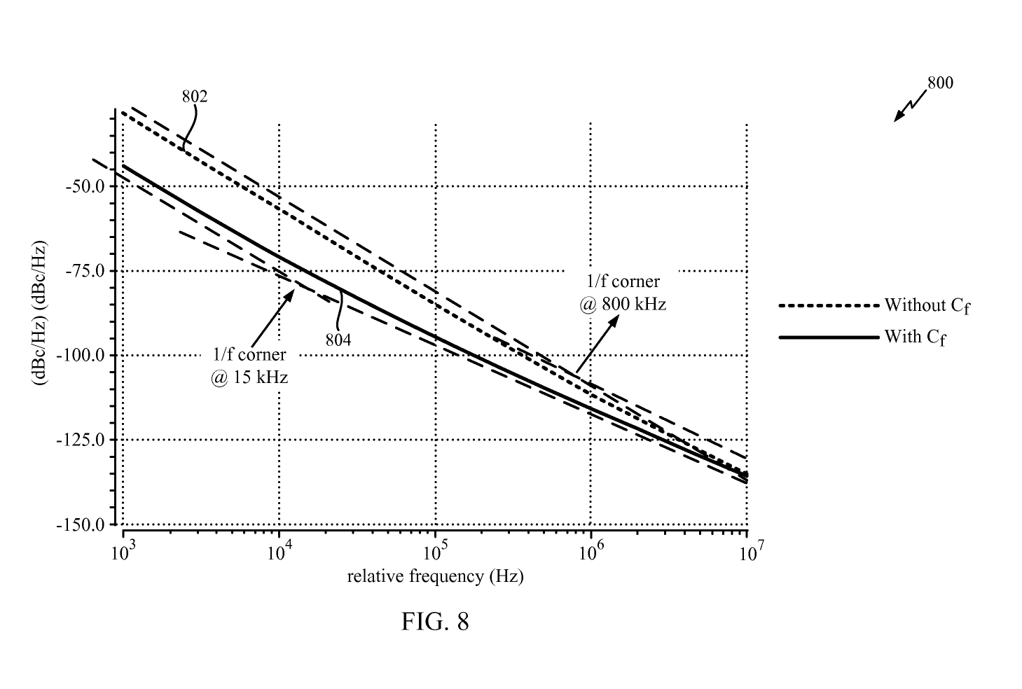

FIG. 8 is an example graph 800 of phase noise (in dBc/Hz) versus frequency (in Hz), where trace 802 represents the phase noise of the VCO 600 of FIG. 6 (without the capacitor Cf and two resistive elements) and trace 804 represents the phase noise of the VCO 700. The l/f corner frequency for trace 802 is at 800 kHz, whereas the l/f corner frequency for trace 804 is much lower at 15 kHz, illustrating the reduced flicker noise with the capacitor Cf and two resistive elements.

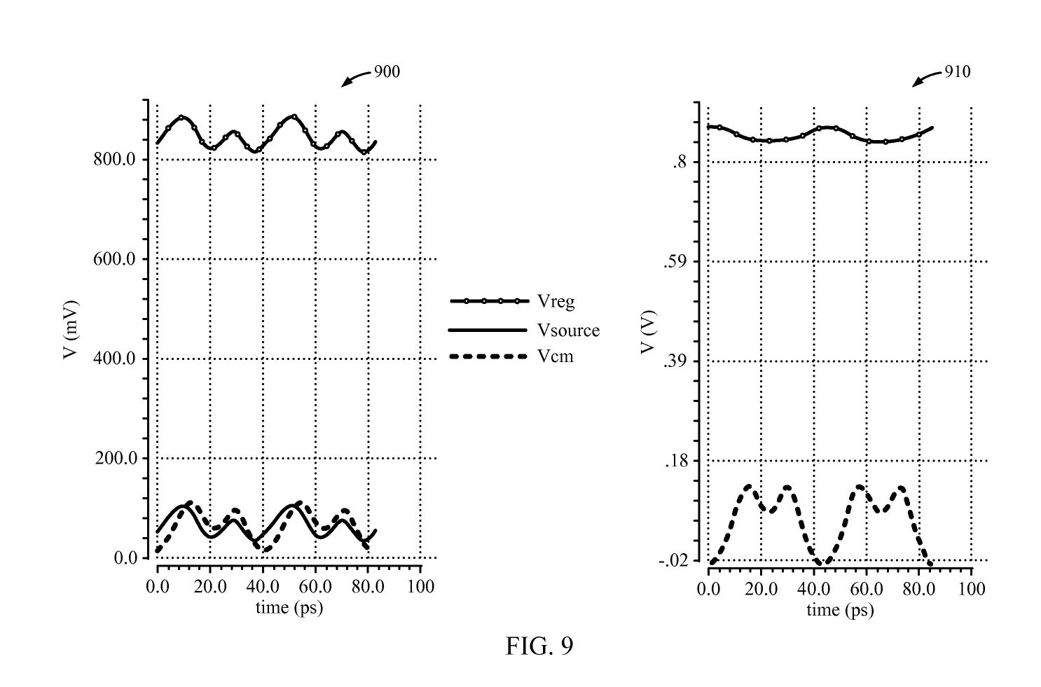

The waveforms in the graph 900 of FIG. 9 represent the amplitudes over time of Vreg, Vcm, and Vsource as labeled in the example VCO 700 of FIG. 7 with the capacitor Cf and the two resistive elements. In the graph 900, the capacitor Cf capacitively couples Vreg and Vcm together, such that Vcm tracks Vreg as illustrated. The graph 910 of FIG. 9 illustrates the waveforms Vreg and Vsource as labeled in the example VCO 600 of FIG. 6 without the capacitor Cf. In the graph 910, Vsource does not follow Vreg.

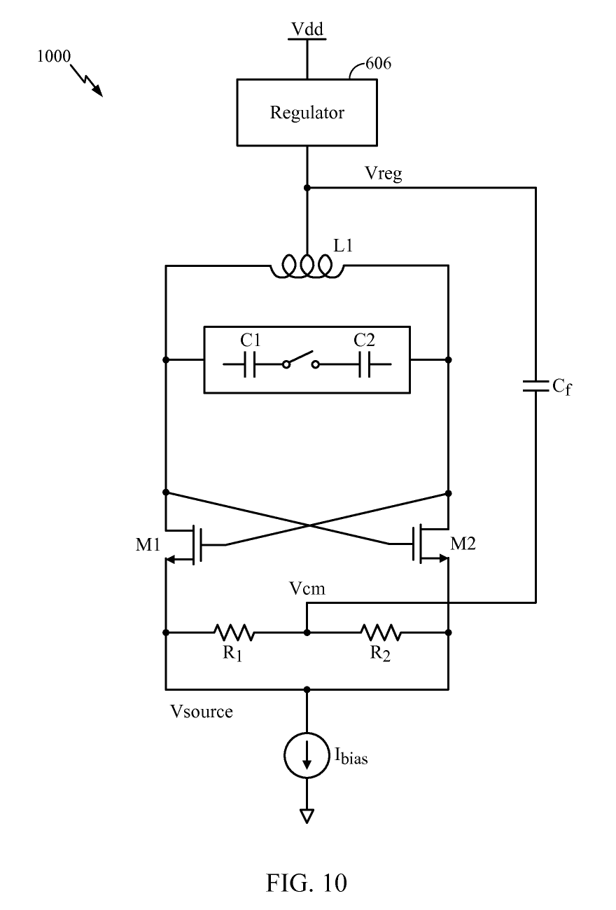

FIG. 10 is a schematic diagram of an example VCO 1000, in accordance with certain aspects of the present disclosure. The VCO 1000 has the capacitor Cf and the two resistive elements (e.g., resistors R1 and R2) for reducing flicker noise, but does not have an additional resonant circuit 530 to reduce VCO pulling. As illustrated, the VCO 1000 includes a bias current source (labeled “Ibias”) for sinking (or sourcing) a bias current through the resonant circuit 602 and the active negative transconductance circuit 604 to generate the oscillating signal output by the VCO.

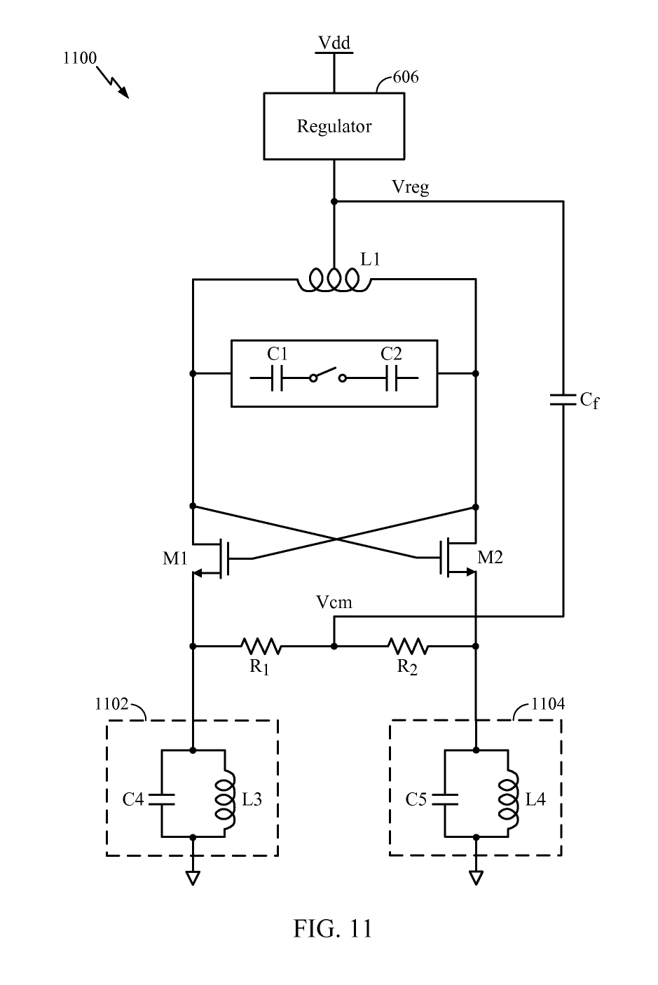

Rather than only a single additional resonant circuit 530, certain aspects of the present disclosure may include more than one additional resonant circuit. For example, FIG. 11 is a schematic diagram of an example VCO 1100 having two additional resonant circuits 1102, 1104 in an effort to reduce VCO pulling, in accordance with certain aspects of the present disclosure. Resonant circuit 1102 may be connected between the source of NMOS transistor M1 and electrical ground (or another reference potential for the VCO 1100), whereas resonant circuit 1104 may be connected between the source of NMOS transistor M2 and the same reference potential. Resonant circuit 1102 may comprise an inductor L3 in parallel with a capacitor C4, either or both of which may be fixed or variable, as described above for resonant circuit 530. Likewise, resonant circuit 1104 may comprise an inductor L4 in parallel with a capacitor C5, either or both of which may be fixed or variable. Both resonant circuits 1102, 1104 may be designed to resonate at the VCO frequency and provide high impedance to currents from the PA 316 at or near 2f_{LO}, thereby preventing these currents from reaching the resonant circuit 602 and influencing the VCO frequency.

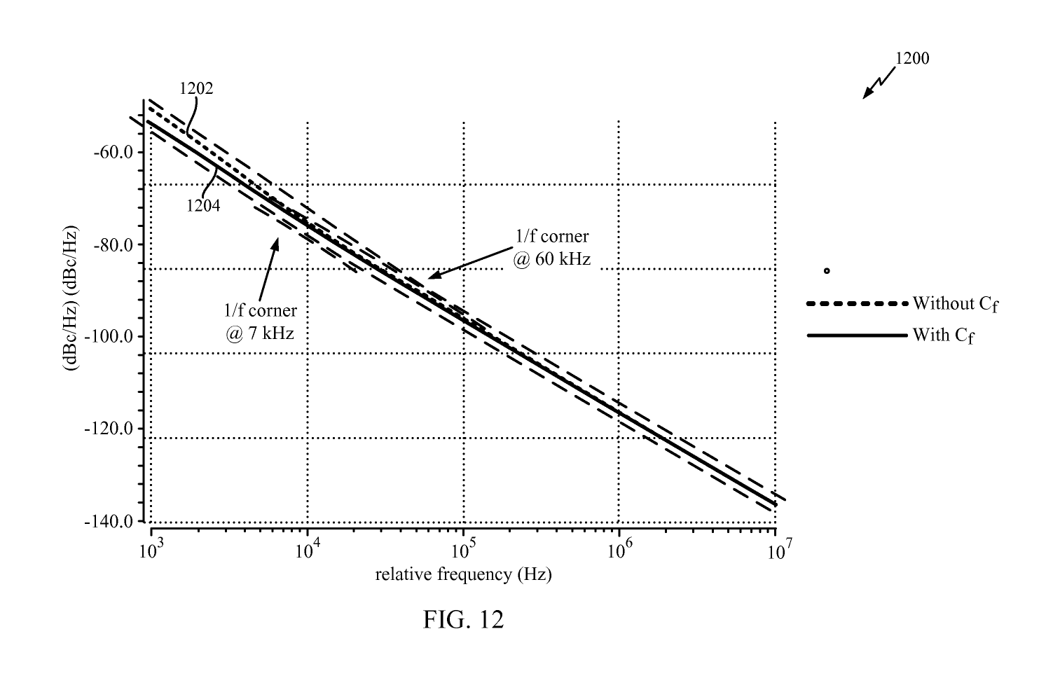

FIG. 12 is an example graph 1200 of phase noise (in dBc/Hz) versus frequency (in Hz), where trace 1202 represents the phase noise of the VCO 1100 of FIG. 11 without the capacitor Cf and two resistive elements and trace 1204 represents the phase noise of the VCO 1100 as illustrated (with the capacitor Cf and resistive elements). The l/f corner frequency for trace 1202 is at 60 kHz, whereas the l/f corner frequency for trace 1204 is lower at 7 kHz, illustrating the reduced flicker noise with the capacitor Cf and two resistive elements.

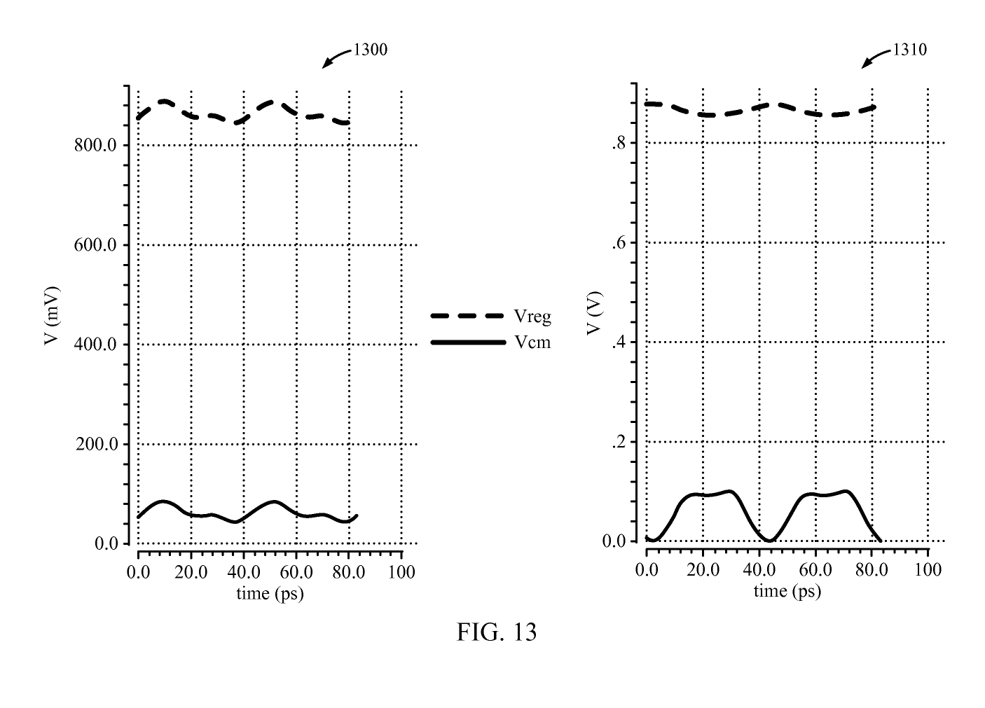

The waveforms in the graph 1300 of FIG. 13 represent the amplitudes over time of Vreg and Vcm as labeled in the example VCO 1100 of FIG. 11 as illustrated (with the capacitor Cf and the two resistive elements). In the graph 1300, the capacitor Cf capacitively couples Vreg and Vcm together, such that Vcm tracks Vreg as illustrated. The graph 1310 of FIG. 13 illustrates the waveforms Vreg and Vcm as labeled in the example VCO 1100 of FIG. 11 without the capacitor Cf. In the graph 1310, Vcm does not follow Vreg.

Although the example VCO circuits described herein are illustrated with NMOS transistors in the active negative transconductance circuit, a person having ordinary skill in the art will understand that any of these VCO circuits may be implemented with PMOS transistors or a CMOS configuration instead.

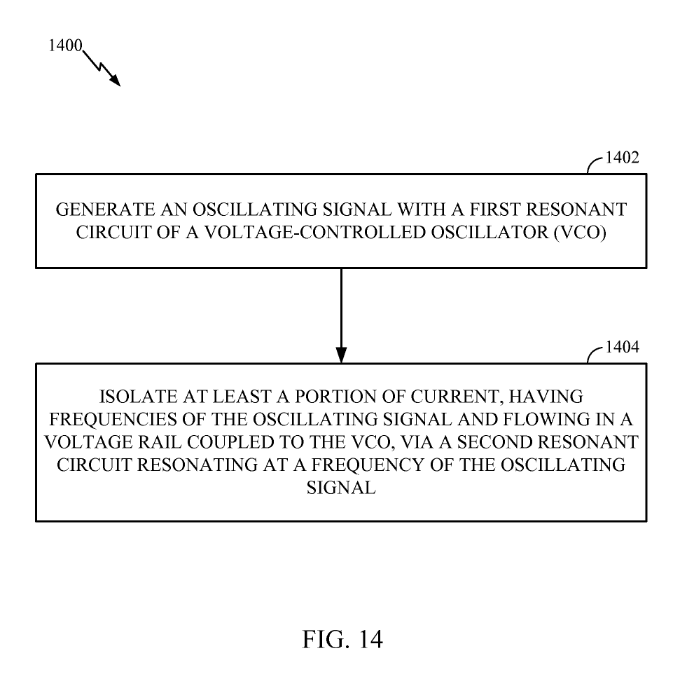

FIG. 14 is a flow diagram of example operations 1400 for reducing noise in an oscillating signal, in accordance with certain aspects of the present disclosure. The operations 1400 may be performed by an apparatus (e.g., a frequency synthesizer, a TX path 302, and/or an RX path 304) comprising a VCO (e.g., VCO 402).

The operations 1400 may begin, at block 1402, with the apparatus generating the oscillating signal with a first resonant circuit (e.g., resonant circuit 602) of a VCO. The first resonant circuit may be configured to control a frequency of the oscillating signal. At block 1404, the apparatus may isolate at least a portion of current, having frequencies of the oscillating signal and flowing in a voltage rail (e.g., Vdd or ground) coupled to the VCO, via a second resonant circuit (e.g., resonant circuit 530, 1102, or 1104) resonating at the frequency of the oscillating signal.

According to certain aspects, the operations 1400 further involve shunting a tuning signal (e.g., Vreg) for the first resonant circuit to a common-mode signal (e.g., Vcm) for the VCO with a capacitive element (e.g., capacitor Cf). This shunting may be performed in an effort to reduce flicker noise in the oscillating signal.

According to certain aspects, the operations 1400 further entail isolating at least another portion of the current flowing in the voltage rail by resonating a third resonant circuit (e.g., resonant circuit 1102 or 1104) at the frequency of the oscillating signal to provide high impedance at the frequency. For certain aspects, the first resonant circuit is connected with an active negative transconductance circuit (e.g., circuit 604) comprising cross-coupled transistors (e.g., NMOS transistors M1 and M2), the second resonant circuit is connected with a source of a first one of the cross-coupled transistors, and the third resonant circuit is connected with a source of a second one of the cross-coupled transistors, different from the first one of the transistors.

According to certain aspects, the operations 1400 further include adjusting the resonating of the second resonant circuit to follow adjustments of the frequency of the oscillating signal.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

For example, means for transmitting may comprise a transmitter (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for receiving may comprise a receiver (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for processing or means for determining may comprise a processing system, which may include one or more processors, such as the RX data processor 270, the TX data processor 288, and/or the controller 280 of the user terminal 120 illustrated in FIG. 2. Means for generating an oscillating signal may comprise a voltage-controlled oscillator (VCO) (e.g., the VCO 600, 700, 1000, or 1100 illustrated in FIG. 6, 7, 10, or 11) and a resonant circuit therein (e.g., resonant circuit 602 depicted in FIG. 6). Means for resonating or means for isolating may comprise a resonant circuit (e.g., additional resonant circuit 530 as illustrated in FIG. 5B or 6 or resonant circuit 1102 or 1104 shown in FIG. 11). Means for shunting a tuning signal may comprise a capacitive element (e.g., capacitor Cf as depicted in FIGS. 7, 10, and 11). Means for adjusting a resonating frequency may comprise a varactor and/or a capacitive network with switches for selecting between capacitive elements to change a capacitance (e.g., a network similar to representative switch S1 and capacitors C1 and C2 may replace capacitor C3 in FIG. 6 and 7 or C4 and/or C5 in FIG. 11).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

1. A voltage-controlled oscillator (VCO), comprising:
an active negative transconductance circuit;
a first resonant circuit connected between a voltage rail for the VCO and the active negative transconductance circuit, wherein the first resonant circuit is configured to resonate at a frequency of an oscillating signal generated by the VCO:,
a second resonant circuit configured to control the frequency of the oscillating signal generated by the VCO; and
a capacitive element coupled between the second resonant circuit and a common-mode voltage for the VCO.

2. The VCO of claim 1, wherein the first resonant circuit is configured to provide high impedance between the voltage rail and the VCO at the frequency of the oscillating signal.

3. The VCO of claim 1, wherein the active negative transconductance circuit comprises cross-coupled transistors and wherein the first resonant circuit is connected with one or more sources of the cross-coupled transistors.

4. The VCO of claim 3, further comprising a third resonant circuit configured to resonate at the frequency of the oscillating signal and to provide high impedance between the voltage rail and a source of a first one of the cross-coupled transistors at the frequency of the oscillating signal, wherein the first resonant circuit is configured to provide high impedance between the voltage rail and a source of a second one of the cross-coupled transistors, different from the first one of the cross-coupled transistors.

5. The VCO of claim 3, wherein the cross-coupled transistors comprise n-channel metal-oxide semiconductor (NMOS) transistors and wherein the voltage rail comprises an electrical ground.

6. The VCO of claim 3, further comprising resistive elements connected in series between the sources of the cross-coupled transistors.

7. The VCO of claim 6, wherein the capacitive element is coupled between the second resonant circuit and the resistive elements.

8. The VCO of claim 7, wherein the capacitive element is coupled between a center tap of an inductive element in the second resonant circuit and a node between the resistive elements.

9. The VCO of claim 6, wherein the resistive elements comprise at least one of a resistor or a transistor biased in a triode region.

10. The VCO of claim 3, wherein the cross-coupled transistors comprise p-channel metal-oxide semiconductor (PMOS) transistors and wherein the voltage rail comprises a power supply voltage configured to supply power to the VCO.

11. The VCO of claim 1, wherein a resonant frequency of the first resonant circuit is adjustable and is configured to follow an adjustment to the frequency of the oscillating signal.

12. The VCO of claim 1, wherein the first resonant circuit is configured to provide high impedance in a frequency band that includes the frequency of the oscillating signal over at least a portion of a tuning range for the VCO.

13. The VCO of claim 1, wherein the first resonant circuit comprises a self-resonating inductor configured to resonate at the frequency of the oscillating signal.

14. Voltage-controlled oscillator (VCO) circuitry, comprising:
a VCO comprising:
a first resonant circuit configured to control a frequency of an oscillating signal generated by the VCO;
an active negative transconductance circuit connected with the first resonant circuit and comprising cross-coupled transistors; and
a capacitive element connected between the first resonant circuit and a common-mode voltage for the VCO, and
a second resonant circuit configured to resonate at the frequency of the oscillating signal and connected between the VCO and a voltage rail of the VCO circuitry.

15. The VCO circuitry of claim 14, further comprising: two or more resistive elements connected in series between sources of the cross-coupled transistors, wherein the capacitive element is connected between the first resonant circuit and the resistive elements.

16. The VCO circuitry of claim 15, wherein the capacitive element is coupled between a center tap of an inductive element in the first resonant circuit and a node between the resistive elements.

17. The VCO circuitry of claim 15, wherein the resistive elements comprise at least one of a resistor or a transistor biased in a triode region.

18. The VCO circuitry of claim 14, further comprising a bias current circuit for sourcing or sinking a bias current through the first resonant circuit and the active negative transconductance circuit to generate the oscillating signal.

19. The VCO circuitry of claim 14, wherein the second resonant circuit is configured to isolate the VCO from at least signals having frequencies of the oscillating signal and emanating from the voltage rail.

20. The VCO circuitry of claim 19, wherein the second resonant circuit is configured to isolate the VCO by providing high impedance between the VCO and the voltage rail for the at least signals having the frequencies of the oscillating signal.

21. A method for reducing noise in an oscillating signal, comprising:
generating the oscillating signal with a first resonant circuit of a voltage-controlled oscillator (VCO);
isolating at least a portion of current, having frequencies of the oscillating signal and flowing in a voltage rail coupled to the VCO, via a second resonant circuit resonating at a frequency of the oscillating signal; and
shunting a tuning signal for the first resonant circuit to a common-mode signal for the VCO with a capacitive element.

22. (canceled)

23. The method of claim 21, further comprising isolating at least another portion of the current flowing in the voltage rail by resonating a third resonant circuit at the frequency of the oscillating signal to provide high impedance at the frequency, wherein the first resonant circuit is connected with an active negative transconductance circuit comprising cross-coupled transistors, wherein the second resonant circuit is connected with a source of a first one of the cross-coupled transistors, and wherein the third resonant circuit is connected with a source of a second one of the cross-coupled transistors, different from the first one of the transistors.

24. The method of claim 21, further comprising adjusting the resonating of the second resonant circuit to follow adjustments of the frequency of the oscillating signal.

25. An apparatus for reducing noise in an oscillating signal, comprising:
means for generating the oscillating signal comprising a first resonant circuit;
means for isolating at least a portion of current, having frequencies of the oscillating signal and flowing in a voltage rail coupled to the means for generating, by resonating a second resonant circuit at a frequency of the oscillating signal; and
means for shunting a tuning signal for the first resonant circuit to a common-mode signal for the means for generating.

26. (canceled)

27. The apparatus of claim 25, further comprising means for adjusting the resonating of the second resonant circuit to follow adjustments of the frequency of the oscillating signal.

28. The apparatus of claim 25, further comprising means for isolating at least another portion of the current flowing in the voltage rail by resonating a third resonant circuit at the frequency of the oscillating signal.
